(19) United States
(12) Patent Application Publication
(10) Pub. No.: US 2017/0002459 A1
(43) Pub. Date: Jan. 5, 2017

(54) Film And Coatings From Nanoscale Graphene Platelets

(71) Applicant: Airbus Defence and Space GmbH, Taufkirchen (DE)

(72) Inventors: Blanka Lenczowski, Neubiberg (DE); Christian Karch, Neubiberg (DE); Ilya Ostrovsky, Hanau (DE)

(73) Assignee: Airbus Defence and Space GmbH, Taufkirchen (DE)

(21) Appl. No.: 15/196,331

(22) Filed: Jun. 29, 2016

(30) Foreign Application Priority Data
Jun. 30, 2015 (DE) 10 2015 008 438.0

(51) Int. Cl. C23C 16/26; C23C 16/56; C23C 16/02

(52) U.S. Cl. CPC C23C 16/26; C23C 16/0272; C23C 16/56; C22C 23/00

(57) ABSTRACT

A composite material includes a magnesium alloy and a layer consisting of nanoscale graphene platelets on at least a part of the surface of the magnesium alloy. A process for manufacturing such a composite material includes providing a magnesium alloy, providing nanoscale graphene platelets and applying the nanoscale graphene platelets to at least a part of the surface of the magnesium alloy.

### FIELD OF THE INVENTION

The present invention relates to a composite material comprising a magnesium alloy and a layer consisting of nanoscale graphene platelets on at least a part of the surface of the magnesium alloy, a process for producing such a composite material, and use of such a composite material.

### BACKGROUND OF THE INVENTION

Magnesium alloys are lighter than aluminium alloys, and are therefore of great interest to the aviation industry. However, many magnesium alloys have a low melting temperature (about 647° C.) and boiling temperature (about 1087° C.) and are highly reactive, in particular with poor resistance to corrosion, with the result that until now use of magnesium alloys has been very limited.

However, the thermal and mechanical properties of magnesium can be improved by the addition of a alloy components such as rare earth metals. For example, magnesium alloys such as WE43, WE54, ZE41, ZE10 or Elektron 21 from Magnesium Elektron, UK, with good mechanical properties at elevated temperatures have already been developed. Due to the addition of rare earth metals these magnesium alloys also have improved ignition and flame resistance. A further possibility consists in coating conventional magnesium alloys such as AZ31B or AZ91E with a corresponding film containing an active flame retardant. Until now, corresponding magnesium alloys have been utilised mainly in the automotive industry.

However, the mechanical and chemical properties of the known magnesium alloys are not adequate for the aviation or automotive industries, and consequently these known magnesium alloys are not optimally suitable for such applications.

### BRIEF SUMMARY OF THE INVENTION

Accordingly, it would be desirable to produce a substance which has improved mechanical properties, particularly improved strength and chemical properties, particularly improved flame and corrosion resistance compared with conventional magnesium alloys. It is also desirable to provide a composite material that presents a lower fire risk and improved resistance to wear and degradation compared with conventional magnesium alloys. It is yet desirable to provide a composite material that can be used as a material in the aviation industry, e.g., passenger transport vehicles and unmanned aircraft, or the automotive industry.

It is also desirable to provide a composite material that weighs less than conventional aluminium alloys and thus contributes generally to a lower overall weight of the vehicles.

An aspect of the present invention may provide a composite material that exhibits improved mechanical properties, particularly improved strength compared with conventional magnesium alloys. Another aspect of the present invention relates to a composite material having improved chemical properties, particularly improved flame and corrosion resistance compared with conventional magnesium alloys. Another aspect of the present invention relates to a composite material presenting a reduced fire risk and improved resistance to wear and degradation compared with conventional magnesium alloys. A further aspect of the present invention relates to a composite material which may be used as a material in the aviation industry, for example in passenger transport vehicles and unmanned aircraft. A further aspect of the present invention relates to a composite material having a low weight, particularly compared with conventional aluminium alloys, and thus contributing generally to lowering the overall weight of the aircraft. A further aspect of the present invention may provide a method for producing such a composite material. In particular, such a method may involve a low production expenditure.

Thus, a first embodiment of the present invention is a composite material comprising
a) a magnesium alloy, and
b) a layer consisting of nanoscale graphene platelets on at least a part of the magnesium alloy surface.

The composite material according to an embodiment of the invention is suitable for use as a material in aircraft, e.g., passenger transport vehicles and unmanned aircraft. A further advantage is that the composite material has improved mechanical properties, particularly improved strength. A further advantage is that the composite material has improved chemical properties, particularly improved flame and corrosion resistance. A further advantage is that the composite material presents a lower risk of fire and improved resistance to wear and degradation compared with conventional magnesium alloys. A further advantage is that the composite material may be manufactured with low production expenditure and has a low weight.

The magnesium alloy comprises for example at least one component selected from the following group as additional alloy component(s): yttrium (Y), neodymium (Nd), terbium (Tb), dysprosium (Dy), holmium (Ho), erbium (Er), thulium (Tm), ytterbium (Yb), lutetium (Lu), zirconium (Zr), zinc (Zn), gadolinium (Gd), scandium (Sc), lanthanum (La), cerium (Ce), praseodymium (Pr), promethium (Pm), samarium (Sm), europium (Eu), aluminium (Al), calcium (Ca), silicon (Si), manganese (Mn), lithium (Li), silver (Ag) or mixtures thereof.

The magnesium alloy contains magnesium in a quantity of 80% to 98% by weight relative to the total weight of the magnesium alloy, for example.

The layer consisting of nanoscale graphene platelets is present substantially over the entire surface of the magnesium alloy, for example.

The layer consisting of nanoscale graphene platelets has a layer thickness from 10 to 1,000 nm, for example.

The layer consisting of nanoscale graphene platelets consists of multiple layers, for example.

The nanoscale graphene platelets have a thickness from 1 to 100 nm and/or a length, width or diameter of ≦100 μm, for example.

The nanoscale graphene platelets are obtained for example by mechanical or chemical processes.

For example, the layer consisting of nanoscale graphene platelets has
a) a thermal conductivity of ≧1 Wm⁻¹K⁻¹, and/or
b) a melting temperature of ≧3725° C., and/or
c) a tensile strength of 1 to 10 GPa, and/or
d) an electrical conductivity of ≦10⁷ ω⁻¹cm⁻¹.

The composite material is obtained for example by the method described herein.

The present invention further provides a process for producing the composite material, wherein the process comprises
a) Providing a magnesium alloy as defined herein,
b) Providing nanoscale graphene platelets as defined herein,
c) Applying the nanoscale graphene platelets from step b) to at least a part of the surface of the magnesium alloy from step a) to produce a composite material.

The nanoscale graphene platelets are applied to at least a part of the surface of the magnesium alloy in step c) by chemical vapour deposition (CVD), epitaxial growth or deposition from an organic matrix, for example.

The magnesium alloy is pretreated before step c) for example by application of an organic or inorganic coating that serves to lower the surface conductivity of the magnesium alloy.

The present invention also relates to the use of the composite material in a passenger transport vehicle, particularly in aircraft such as airliners, helicopters or unmanned aircraft, for example in an airframe, a spacecraft, a transport vehicle, particularly in railways and ships, automobile construction, plant construction, machine building or toolmaking.

### DETAILED DESCRIPTION OF THE INVENTION

The present invention relates to a composite material comprising
a) a magnesium alloy, and
b) a layer consisting of nanoscale graphene platelets on at least a part of the magnesium alloy surface.

Accordingly, one aspect of the present invention is that the composite material comprises a magnesium alloy. The use of magnesium alloys is advantageous because they have low weight, particularly compared with aluminium alloys, and thus contribute to a lower total weight of the aircraft.

The magnesium alloy preferably comprises at least one rare earth metal as a further alloy component. The advantage of this is that magnesium alloys have good mechanical properties at elevated temperatures and improved ignition and flame resistance.

In one embodiment of the present invention, the magnesium alloy therefore comprises as a further alloy component preferably at least one component selected from the group comprising yttrium (Y), neodymium (Nd), terbium (Tb), dysprosium (Dy), holmium (Ho), erbium (Er), thulium (Tm), ytterbium (Yb), lutetium (Lu), zirconium (Zr), zinc (Zn), gadolinium (Gd), scandium (Sc), lanthanum (La), cerium (Ce), praseodymium (Pr), promethium (Pm), samarium (Sm), europium (Eu), aluminium (Al), calcium (Ca), silicon (Si), manganese (Mn), lithium (Li), silver (Ag) or mixtures thereof as the further alloy component.

For example, the magnesium alloy comprises at least two further alloy components as the further alloy component, for example two components selected from the group comprising yttrium (Y), neodymium (Nd), terbium (Tb), dysprosium (Dy), holmium (Ho), erbium (Er), thulium (Tm), ytterbium (Yb), lutetium (Lu), zirconium (Zr), zinc (Zn), gadolinium (Gd), scandium (Sc), lanthanum (La), cerium (Ce), praseodymium (Pr), promethium (Pm), samarium (Sm), europium (Eu), aluminium (Al), calcium (Ca), silicon (Si), manganese (Mn), lithium (Li) and silver (Ag).

Alternatively, the magnesium alloy comprises at least three further alloy components as the further alloy component, for example three components selected from the group comprising yttrium (Y), neodymium (Nd), terbium (Tb), dysprosium (Dy), holmium (Ho), erbium (Er), thulium (Tm), ytterbium (Yb), lutetium (Lu), zirconium (Zr), zinc (Zn), gadolinium (Gd), scandium (Sc), lanthanum (La), cerium (Ce), praseodymium (Pr), promethium (Pm), samarium (Sm), europium (Eu), aluminium (Al), calcium (Ca), silicon (Si), manganese (Mn), lithium (Li) and silver (Ag).

In one embodiment, the magnesium alloy comprises yttrium (Y) and zirconium (Zr) as the further alloy component.

In a further embodiment, the magnesium alloy comprises yttrium (Y), zirconium (Zr), and at least one component, one or two or three components selected from the group comprising neodymium (Nd), terbium (Tb), dysprosium (Dy), holmium (Ho), erbium (Er), thulium (Tm), ytterbium (Yb), lutetium (Lu), zinc (Zn), gadolinium (Gd), scandium (Sc), lanthanum (La), cerium (Ce), praseodymium (Pr), promethium (Pm), samarium (Sm), europium (Eu), aluminium (Al), calcium (Ca), silicon (Si), manganese (Mn), lithium (Li) and silver (Ag) as the additional alloy component.

Alternatively, the magnesium alloy comprises yttrium (Y), neodymium (Nd) and zirconium (Zr) as the additional alloy component.

In one embodiment, the magnesium alloy comprises yttrium (Y), neodymium (Nd), zirconium (Zr) and at least one component, one or two or three components selected from the group comprising terbium (Tb), dysprosium (Dy), holmium (Ho), erbium (Er), thulium (Tm), ytterbium (Yb), lutetium (Lu), zinc (Zn), gadolinium (Gd), scandium (Sc), lanthanum (La), cerium (Ce), praseodymium (Pr), promethium (Pm), samarium (Sm), europium (Eu), aluminium (Al), calcium (Ca), silicon (Si), manganese (Mn), lithium (Li) and silver (Ag) as the additional alloy component.

In one embodiment of the present invention, the magnesium alloy comprises at least one component, for example, two or three or four components, selected from the group comprising yttrium (Y), neodymium (Nd), terbium (Tb), dysprosium (Dy), holmium (Ho), ytterbium (Yb), lutetium (Lu), zirconium (Zr), zinc (Zn), gadolinium (Gd), scandium (Sc), lanthanum (La), cerium (Ce), aluminium (Al), calcium (Ca), silicon (Si), manganese (Mn), lithium (Li) and silver (Ag) as the additional alloy component.

The magnesium alloy exhibits particularly good mechanical properties at elevated temperatures and improved ignition and flame resistance when the at least one further alloy component is contained in a certain quantity.

The magnesium alloy therefore comprises magnesium (Mg) preferably in a quantity of 80 to 98% by weight relative to the total weight of the magnesium alloy.

For example, the magnesium alloy preferably comprises magnesium (Mg) in a quantity from 89 to 96% by weight relative to the total weight of the magnesium alloy.

In one embodiment, the magnesium alloy comprises magnesium (Mg) in a quantity from 89 to 94% by weight, relative to the total weight of the magnesium alloy.

The magnesium alloy comprises magnesium (Mg) and the at least one additional alloy component, selected from the group comprising yttrium (Y), neodymium (Nd), terbium (Tb), dysprosium (Dy), holmium (Ho), erbium (Er), thulium (Tm), ytterbium (Yb), lutetium (Lu), zirconium (Zr), zinc (Zn), gadolinium (Gd), scandium (Sc), lanthanum (La), cerium (Ce), praseodymium (Pr), promethium (Pm), samarium (Sm), europium (Eu), aluminium (Al), calcium (Ca), silicon (Si), manganese (Mn), lithium (Li) and silver (Ag) or mixtures thereof preferably in a total quantity of at least 90% by weight relative to the total weight of the magnesium alloy.

For example, the magnesium alloy comprises magnesium (Mg) and the at least one further alloy component selected from the group comprising yttrium (Y), neodymium (Nd), terbium (Tb), dysprosium (Dy), holmium (Ho), erbium (Er), thulium (Tm), ytterbium (Yb), lutetium (Lu), zirconium (Zr), zinc (Zn), gadolinium (Gd), scandium (Sc), lanthanum (La), cerium (Ce), praseodymium (Pr), promethium (Pm), samarium (Sm), europium (Eu), aluminium (Al), calcium (Ca), silicon (Si), manganese (Mn), lithium (Li), silver (Ag) or mixtures thereof preferably in a total quantity of at least 91% by weight, preferably in total quantity of at least 92% by weight and most preferably in a total quantity of at least 93% by weight relative to the total weight of the magnesium alloy.

In one embodiment of the present invention, the magnesium alloy comprises magnesium (Mg) and the at least one further alloy component selected from the group comprising yttrium (Y), neodymium (Nd), terbium (Tb), dysprosium (Dy), holmium (Ho), erbium (Er), thulium (Tm), ytterbium (Yb), lutetium (Lu), zirconium (Zr), zinc (Zn), gadolinium (Gd), scandium (Sc), lanthanum (La), cerium (Ce), praseodymium (Pr), promethium (Pm), samarium (Sm), europium (Eu), aluminium (Al), calcium (Ca), silicon (Si), manganese (Mn), lithium (Li), silver (Ag) or mixtures thereof preferably in a total quantity of at least 94% by weight, more preferably in a total quantity of at least 96% by weight, even more preferably in a total quantity of at least 98%, and most preferably in a total quantity of at least 99% by weight relative to the total weight of the magnesium alloy.

In one embodiment of the present invention, the magnesium alloy comprises magnesium (Mg) and the at least one further alloy component selected from the group comprising yttrium (Y), neodymium (Nd), terbium (Tb), dysprosium (Dy), holmium (Ho), erbium (Er), thulium (Tm), ytterbium (Yb), lutetium (Lu), zirconium (Zr), zinc (Zn), gadolinium (Gd), scandium (Sc), lanthanum (La), cerium (Ce), praseodymium (Pr), promethium (Pm), samarium (Sm), europium (Eu), aluminium (Al), calcium (Ca), silicon (Si), manganese (Mn), lithium (Li), silver (Ag) or mixtures thereof preferably in a total quantity of 90 to 100% by weight, or in a total quantity of 90 to 99.99% by weight relative to the total weight of the magnesium alloy.

For example, the magnesium alloy comprises magnesium (Mg) and the at least one further alloy component selected from the group comprising yttrium (Y), neodymium (Nd), terbium (Tb), dysprosium (Dy), holmium (Ho), erbium (Er), thulium (Tm), ytterbium (Yb), lutetium (Lu), zirconium (Zr), zinc (Zn), gadolinium (Gd), scandium (Sc), lanthanum (La), cerium (Ce), praseodymium (Pr), promethium (Pm), samarium (Sm), europium (Eu), aluminium (Al), calcium (Ca), silicon (Si), manganese (Mn), lithium (Li) and silver (Ag) or mixtures thereof preferably in a total quantity of 90 to 99.95% by weight, more preferably in a total quantity of 90 to 99.5% by weight, and most preferably in a total quantity of 90 to 99.45% by weight relative to the total weight of the magnesium alloy.

In one embodiment of the present invention, the magnesium alloy comprises magnesium (Mg) and the at least one further alloy component selected from the group comprising yttrium (Y), neodymium (Nd), terbium (Tb), dysprosium (Dy), holmium (Ho), erbium (Er), thulium (Tm), ytterbium (Yb), lutetium (Lu), zirconium (Zr), zinc (Zn), gadolinium (Gd), scandium (Sc), lanthanum (La), cerium (Ce), praseodymium (Pr), promethium (Pm), samarium (Sm), europium (Eu), aluminium (Al), calcium (Ca), silicon (Si), manganese (Mn), lithium (Li), silver (Ag) or mixtures thereof preferably in a total quantity of 94 to 99.95% by weight, more preferably in a total quantity of 94 to 99.5% by weight, and most preferably in a total quantity of 94 to 99.45% by weight relative to the total weight of the magnesium alloy.

Alternatively, the magnesium alloy comprises magnesium (Mg) and the at least one further alloy component selected from the group comprising yttrium (Y), neodymium (Nd), terbium (Tb), dysprosium (Dy), holmium (Ho), erbium (Er), thulium (Tm), ytterbium (Yb), lutetium (Lu), zirconium (Zr), zinc (Zn), gadolinium (Gd), scandium (Sc), lanthanum (La), cerium (Ce), praseodymium (Pr), promethium (Pm), samarium (Sm), europium (Eu), aluminium (Al), calcium (Ca), silicon (Si), manganese (Mn), lithium (Li), silver (Ag) or mixtures thereof preferably in a total quantity of 98 to 99.95% by weight, more preferably in a total quantity of 98 to 99.5% by weight, and most preferably in a total quantity of 98 to 99.45% by weight relative to the total weight of the magnesium alloy.

The magnesium alloy comprises the at least one further alloy component selected from the group comprising yttrium (Y), neodymium (Nd), terbium (Tb), dysprosium (Dy), holmium (Ho), erbium (Er), thulium (Tm), ytterbium (Yb), lutetium (Lu), zirconium (Zr), zinc (Zn), gadolinium (Gd), scandium (Sc), lanthanum (La), cerium (Ce), praseodymium (Pr), promethium (Pm), samarium (Sm), europium (Eu), aluminium (Al), calcium (Ca), silicon (Si), manganese (Mn), lithium (Li), silver (Ag) or mixtures thereof preferably in a total quantity from 2 to 20% by weight relative to the total weight of the magnesium alloy.

For example, the magnesium alloy comprises the at least one further alloy component selected from the group comprising yttrium (Y), neodymium (Nd), terbium (Tb), dysprosium (Dy), holmium (Ho), erbium (Er), thulium (Tm), ytterbium (Yb), lutetium (Lu), zirconium (Zr), zinc (Zn), gadolinium (Gd), scandium (Sc), lanthanum (La), cerium (Ce), praseodymium (Pr), promethium (Pm), samarium (Sm), europium (Eu), aluminium (Al), calcium (Ca), silicon (Si), manganese (Mn), lithium (Li), silver (Ag) or mixtures thereof preferably in a total quantity from 4 to 11% by weight relative to the total weight of the magnesium alloy.

In one embodiment, the magnesium alloy comprises the at least one further alloy component selected from the group comprising yttrium (Y), neodymium (Nd), terbium (Tb), dysprosium (Dy), holmium (Ho), erbium (Er), thulium (Tm), ytterbium (Yb), lutetium (Lu), zirconium (Zr), zinc (Zn), gadolinium (Gd), scandium (Sc), lanthanum (La), cerium (Ce), praseodymium (Pr), promethium (Pm), samarium (Sm), europium (Eu), aluminium (Al), calcium (Ca), silicon (Si), manganese (Mn), lithium (Li), silver (Ag) or mixtures thereof in a total quantity from 6 to 11% by weight relative to the total weight of the magnesium alloy.

In one embodiment of the present invention, the magnesium alloy comprises the at least one further alloy component selected from the group comprising yttrium (Y), neodymium (Nd), terbium (Tb), dysprosium (Dy), holmium (Ho), erbium (Er), thulium (Tm), ytterbium (Yb), lutetium (Lu), zirconium (Zr), zinc (Zn), gadolinium (Gd), scandium (Sc), lanthanum (La), cerium (Ce), praseodymium (Pr), promethium (Pm), samarium (Sm), europium (Eu), aluminium (Al), calcium (Ca), silicon (Si), manganese (Mn), lithium (Li), silver (Ag) or mixtures thereof in a total quantity from 0.05 to 6% per element relative to the total weight of the magnesium alloy.

For example, the magnesium alloy comprises the at least one further alloy component selected from the group comprising yttrium (Y), neodymium (Nd), terbium (Tb), dysprosium (Dy), holmium (Ho), erbium (Er), thulium (Tm), ytterbium (Yb), lutetium (Lu), zirconium (Zr), zinc (Zn), gadolinium (Gd), scandium (Sc), lanthanum (La), cerium (Ce), praseodymium (Pr), promethium (Pm), samarium (Sm), europium (Eu), aluminium (Al), calcium (Ca), silicon (Si), manganese (Mn), lithium (Li), silver (Ag) or mixtures thereof in a total quantity from 0.1 to 5.5% per element relative to the total weight of the magnesium alloy.

In order to obtain a magnesium alloy with good mechanical properties at elevated temperatures as well as improved ignition and flame resistance, it is advantageous if the magnesium alloy comprises yttrium (Y) as at least one further alloy component.

If the magnesium alloy comprises yttrium (Y) as at least one further alloy component, the magnesium alloy preferably comprises yttrium (Y) in a quantity from 0.05 to 6% by weight relative to the total weight of the magnesium alloy. For example, the magnesium alloy comprises yttrium (Y) in a quantity from 0.1 to 5.5% by weight relative to the total weight of the magnesium alloy. In one embodiment the magnesium alloy comprises yttrium (Y) in a quantity from 2 to 5.5% by weight relative to the total weight of the magnesium alloy. In a preferred embodiment, the magnesium alloy comprises yttrium (Y) in a quantity from 4.5 to 5.5% by weight relative to the total weight of the magnesium alloy. Alternatively, the magnesium alloy comprises yttrium (Y) in a quantity from 3.5 to 4.5% by weight relative to the total weight of the magnesium alloy.

In order to obtain a magnesium alloy with good mechanical properties at elevated temperatures as well as improved ignition and flame resistance, it is advantageous if the magnesium alloy additionally or alternatively comprises zirconium (Zr) as at least one further alloy component.

If the magnesium alloy comprises zirconium (Zr) as at least one further alloy component, the magnesium alloy preferably comprises zirconium (Zr) in a quantity from 0.05 to 6% by weight relative to the total weight of the magnesium alloy. For example, the magnesium alloy comprises zirconium (Zr) in a quantity from 0.1 to 5.5% by weight relative to the total weight of the magnesium alloy. In one embodiment the magnesium alloy comprises zirconium (Zr) in a quantity from 0.2 to 1% by weight relative to the total weight of the magnesium alloy. In a preferred embodiment, the magnesium alloy comprises zirconium (Zr) in a quantity from 0.2 to 0.5% by weight relative to the total weight of the magnesium alloy.

In order to obtain a magnesium alloy with good mechanical properties at elevated temperatures as well as improved ignition and flame resistance, it is advantageous if the magnesium alloy additionally or alternatively comprises neodymium (Nd) as at least one further alloy component.

If the magnesium alloy comprises neodymium (Nd) as at least one further alloy component, the magnesium alloy preferably comprises neodymium (Nd) in a quantity from 0.05 to 6% by weight relative to the total weight of the magnesium alloy. For example, the magnesium alloy comprises neodymium (Nd) in a quantity from 0.1 to 5.5% by weight relative to the total weight of the magnesium alloy. In one embodiment the magnesium alloy comprises neodymium (Nd) in a quantity from 0.5 to 3.5% by weight relative to the total weight of the magnesium alloy. For example, the magnesium alloy comprises neodymium (Nd) in a quantity of 1.5 to 2% by weight relative to the total weight of the magnesium alloy. Alternatively, the magnesium alloy comprises neodymium (Nd) in a quantity of 2.5 to 3.2% by weight relative to the total weight of the magnesium alloy.

For example, the magnesium alloy comprises yttrium (Y) and zirconium (Zr) as the further alloy component. In this embodiment the magnesium alloy comprises yttrium (Y) and zirconium (Zr) in a total quantity of 2 to 15% by weight relative to the total weight of the magnesium alloy. In one embodiment, the magnesium alloy comprises yttrium (Y) and zirconium (Zr) preferably in a total quantity from 2 to 10% by weight relative to the total weight of the magnesium alloy. In a preferred embodiment the magnesium alloy comprises yttrium (Y) and zirconium (Zr) preferably in a total quantity from 3.5 to 6% by weight relative to the total weight of the magnesium alloy.

For example, the magnesium alloy comprises yttrium (Y) and zirconium (Zr) in a total quantity from 5.1 to 6% by weight relative to the total weight of the magnesium alloy. In this embodiment the magnesium alloy comprises yttrium (Y) preferably in a quantity from 4.75 to 5.5% by weight and zirconium (Zr) in a quantity von 0.35 to 0.5% by weight relative to the total weight of the magnesium alloy.

Alternatively, the magnesium alloy comprises yttrium (Y) and zirconium (Zr) in a total quantity from 3.8 to 5% by weight relative to the total weight of the magnesium alloy. In this embodiment the magnesium alloy comprises yttrium (Y) preferably in a quantity from 3.7 to 4.3% by weight and zirconium (Zr) in a quantity from 0.1 to 0.7% by weight relative to the total weight of the magnesium alloy.

In one embodiment, the magnesium alloy comprises yttrium (Y), neodymium (Nd) and zirconium (Zr) as the further alloy component. In this embodiment the magnesium alloy comprises yttrium (Y), neodymium (Nd) and zirconium (Zr) in a total quantity from 2 to 15% by weight relative to the total weight of the magnesium alloy. In one embodiment the magnesium alloy comprises yttrium (Y), neodymium (Nd) and zirconium (Zr) preferably in a total quantity from 2 to 10% by weight relative to the total weight of the magnesium alloy. In a preferred embodiment, the magnesium alloy comprises yttrium (Y), neodymium (Nd) and zirconium (Zr) preferably in a total quantity from 3.5 to 8% by weight relative to the total weight of the magnesium alloy.

For example, the magnesium alloy comprises yttrium (Y), neodymium (Nd) and zirconium (Zr) in a total quantity from 5 to 8% by weight relative to the total weight of the magnesium alloy.

Alternatively, the magnesium alloy comprises yttrium (Y), neodymium (Nd) and zirconium (Zr) in a total quantity from 6.6 to 8% by weight relative to the total weight of the magnesium alloy. In this embodiment the magnesium alloy comprises yttrium (Y) preferably in a quantity from 4.75 to 5.5% by weight, zirconium (Zr) in a quantity from 0.35 to 0.5% by weight and neodymium (Nd) in a quantity from 1.5 to 2% by weight relative to the total weight of the magnesium alloy.

As a consequence of the manufacturing process, the magnesium alloy may contain impurities in the form of other elements, i.e., elements which are not selected from the group comprising yttrium (Y), neodymium (Nd), terbium (Tb), dysprosium (Dy), holmium (Ho), erbium (Er), thulium (Tm), ytterbium (Yb), lutetium (Lu), zirconium (Zr), zinc (Zn), gadolinium (Gd), scandium (Sc), lanthanum (La), cerium (Ce), praseodymium (Pr), promethium (Pm), samarium (Sm), europium (Eu), aluminium (Al), calcium (Ca), silicon (Si), manganese (Mn), lithium (Li), silver (Ag) or mixtures thereof. For example, the magnesium alloy comprises impurities in a quantity from 0.01 to 1.0% by weight per element relative to the total weight of the magnesium alloy.

Such impurities may be selected for example from the group comprising iron (Fe), copper (Cu) and/or nickel (Ni).

In addition or alternatively thereto, the magnesium alloy comprises impurities in a total quantity not exceeding 10% by weight relative to the total weight of the magnesium alloy. For example, the magnesium alloy comprises the impurities in a total quantity from 0.05 to 2% by weight, preferably from 0.5 to 2% by weight and most preferably from 0.55 to 2% by weight relative to the total weight of the magnesium alloy.

Magnesium alloys of the composite material according to the invention are known in the prior art, and can be obtained with known manufacturing processes. Such magnesium alloys are commercially available under the names WE43, WE54, ZE41, ZE10 or Elektron 21 from Magnesium Elektron, UK, for example.

A further aspect of the present invention is particularly that the composite material has a layer consisting of nanoscale graphene platelets on at least a part of the magnesium alloy surface.

For the purposes of the present invention, the term “nanoscale” graphene platelets is understood to mean nanoscale graphene platelets with a length, width or diameter that is in the nanometre to lower micrometre range. In one embodiment, the nanoscale graphene platelets have a length, width or diameter of ≦100 μm. For example, the nanoscale graphene platelets have a length, width or diameter of ≦50 μm. In one embodiment, the nanoscale graphene platelets have a length, width or diameter from 1 to 100 μm.

Additionally or alternatively thereto, the nanoscale graphene platelets have a thickness of 1 to 100 nm.

For example, the nanoscale graphene platelets have a thickness from 1 to 100 nm and a length, width or diameter of ≦100 μm, preferably of ≦50 μm. In one embodiment, the nanoscale graphene platelets have a thickness from 1 to 100 nm and a length, width or diameter of from 1 to 100 μm. The use of nanoscale graphene platelets has the advantage that they can be packed more closely together on the magnesium alloy than CNTs, for example, which in turn means that the magnesium alloy surface can essentially be coated completely.

The nanoscale graphene platelets are planar, spherical, non-spherical, or mixtures thereof, for example. The nanoscale graphene platelets are preferably non-spherical, for example the nanoscale graphene platelets are planar.

The planar graphene platelets typically have a ratio of thickness/length or width in the order of 10 to 1000, preferably 100 to 500.

Non-spherical nanoparticles are present in an aspect ratio that differs from the spherical particles, that is to say the aspect ratio of the non-spherical nanoparticles is not from 1.0 to 2.0. If the nanoscale graphene platelets are present as non-spherical particles, the diameter of the nanoscale graphene platelets preferably refers to the shorter dimension.

It is particularly advantageous for the composite material if said material comprises a layer consisting of nanoscale graphene platelets on at least a part of the magnesium alloy surface. In this way, it is possible particularly to reduce the risk of fire and improve wear and degradation resistance compared with conventional magnesium alloys.

It is particularly advantageous if at least 50% of the surface of the magnesium alloy is coated with a layer consisting of nanoscale graphene platelets. For example, at least 70%, more preferably at least 80%, yet more preferably at least 90%, even more preferably at least 95% and most preferably at least 98% of the surface of the magnesium alloy is coated with a layer consisting of nanoscale graphene platelets. In one embodiment, substantially the entire surface of the magnesium alloy is coated with a layer consisting of nanoscale graphene platelets.

It is advantageous if the layer consisting of nanoscale graphene platelets is substantially free of pores.

In one embodiment of the present invention substantially the entire surface of the magnesium alloy is covered with graphene platelets, and the layer consisting of nanoscale graphene platelets is substantially free of pores.

It is particularly advantageous for the composite material if the layer consisting of nanoscale graphene platelets is homogenously distributed on the magnesium alloy.

Alternatively, the layer consisting of nanoscale graphene platelets may be inhomogenously distributed on the magnesium alloy.

In one embodiment, the layer consisting of nanoscale graphene platelets is in place substantially over the entire surface of the magnesium alloy. This is particularly advantageous for improving the mechanical properties, particularly strength, and the chemical properties, particularly flame and corrosion resistance. Moreover, this may also help to reduce the risk of fire and improve resistance to wear and degradation compared with conventional magnesium alloys.

Moreover, it is advantageous for the mechanical and chemical properties if the layer consisting of nanoscale graphene platelets has a layer thickness of not less than 10 nm. In addition, no significant improvement in terms of mechanical and chemical properties is gained if the layer consisting of nanoscale graphene platelets has a layer thickness of more than 1,000 nm. Therefore, the layer consisting of nanoscale graphene platelets preferably has a layer thickness from 10 to 1,000 nm. For example, the layer consisting of nanoscale graphene platelets preferably has a layer thickness from 10 to 500 nm.

The layer thickness of the layer consisting of nanoscale graphene platelets preferably refers to the average layer thickness.

In one embodiment, the layer consisting of nanoscale graphene platelets consists of multiple layers. For example, the layer consisting of nanoscale graphene platelets consists of two or three or four layers. The layer consisting of nanoscale graphene platelets preferably consists of two or three layers, more preferably of two layers. The layer consisting of nanoscale graphene platelets preferably has a total layer thickness from 10 to 1,000 nm. For example, the layer consisting of nanoscale graphene platelets preferably has a total layer thickness from 10 to 500 nm.

In one embodiment, the layer consisting of nanoscale graphene platelets is applied directly to the magnesium alloy on at least a part of the magnesium alloy surface.

The nanoscale graphene platelets may be obtained by mechanical or chemical processes.

If the nanoscale graphene platelets are obtained by mechanical processes, the nanoscale graphene platelets are preferably obtained by exfoliation, cauterising the Si in the SiC crystal, descaling or platelet separation from a natural graphite, synthetic graphite, highly oriented pyrolytic graphite, carbon nanofibres, graphite nanofibres, nodular graphite, mesophase pitch, graphite coke or mixtures thereof.

Alternatively, the nano scale graphene platelets are obtained by chemical processes such as by reduction of graphene oxide, or also by epitaxial growth.

The layer consisting of nanoscale graphene platelets preferably has
a) a thermal conductivity of ≧1 Wm⁻¹K⁻¹, and/or
b) a melting temperature of ≧3725° C., and/or
c) a tensile strength of 1 to 10 GPa, and/or
d) an electrical conductivity of ≦10⁷ ω⁻¹cm⁻¹.

In one embodiment, the layer consisting of nanoscale graphene platelets has a thermal conductivity of ≧1 Wm⁻¹K⁻¹, preferably ≧100 Wm⁻¹K⁻¹, more preferably ≧250 Wm⁻¹K⁻¹, most preferably in a range from 1 to 5,000 Wm⁻¹K⁻¹, for example from 1 to 4,000 Wm⁻¹K⁻¹. Unless indicated otherwise, thermal conductivity was determined in accordance with ASTM E1461.

In addition or alternatively thereto, the layer consisting of nanoscale graphene platelets has a melting temperature of ≧3725° C., preferably ≧4000° C., more preferably ≧4500° C., most preferably in a range from 4500 to 5000° C. Unless indicated otherwise, the melting temperature was determined in accordance with ASTM D3418.

In addition or alternatively thereto, the layer consisting of nanoscale graphene platelets has a tensile strength from 1 to 10 GPa, preferably 1 to 8 GPa, more preferably 2 to 8 GPa, most preferably 3 to 8 GPa. Unless indicated otherwise, the tensile strength was determined in accordance with ASTM 638.

In addition or alternatively thereto, the layer consisting of nanoscale graphene platelets has an electrical conductivity from ≦10⁷ Ω⁻¹cm⁻¹ and preferably in a range from 10³ to 10⁷ Ω⁻¹cm⁻¹. Unless indicated otherwise, the electrical conductivity was determined in accordance with ASTM D 257.

For example, the layer consisting of nanoscale graphene platelets has
a) a thermal conductivity of ≧1 Wm⁻¹K⁻¹, preferably ≧100 Wm⁻¹K⁻¹, more preferably ≧250 Wm⁻¹K⁻¹, most preferably in a range from 1 to 5000 Wm⁻¹K⁻¹, for example from 1 to 4000 Wm⁻¹K⁻¹, or
b) a melting temperature of ≧3725° C., preferably ≧4000° C., more preferably ≧4500° C., most preferably in a range from 4500 to 5000° C., or
c) a tensile strength of 1 to 10 GPa, preferably 1 to 8 GPa, more preferably 2 to 8 GPa, most preferably 3 to 8 GPa, or
d) an electrical conductivity of ≦10⁷ Ω⁻¹cm⁻¹, preferably in a range from 10³ to 10⁷ Ω⁻¹cm⁻¹.

Alternatively, the layer consisting of nanoscale graphene platelets has
a) a thermal conductivity of ≧1 Wm⁻¹K⁻¹, preferably ≧100 Wm⁻¹K⁻¹, more preferably ≧250 Wm⁻¹K⁻¹, most preferably in a range from 1 to 5,000 Wm⁻¹K⁻¹, for example from 1 to 4,000 Wm⁻¹K⁻¹, and
b) a melting temperature of ≧3725° C., preferably ≧4000° C., more preferably ≧4500° C., most preferably in a range from 4500 to 5000° C., and
c) a tensile strength of 1 to 10 GPa, preferably 1 to 8 GPa, more preferably 2 to 8 GPa, most preferably from 3 to 8 GPa, and
d) an electrical conductivity of ≦10⁷ Ω⁻¹cm⁻¹, preferably in a range from 10³ to 10⁷ Ω⁻¹cm⁻¹.

The composite material according to an embodiment of the invention has improved mechanical properties, particularly improved strength, and improved chemical properties, particularly improved flame and corrosion resistance. The composite material according to an embodiment of the invention also presents a reduced risk of fire and has improved resistance to wear and degradation compared with conventional magnesium alloys. Moreover, the composite material is lighter than conventional aluminium alloys and is particularly suitable for use as a material in aircraft.

The present invention also relates to a process for producing such a composite material. The composite material is preferably produced in a process such as is described in the following.

The process according to the invention referred to above for producing the composite material, comprises at least the following steps:
a) Providing a magnesium alloy as defined herein,
b) Providing nanoscale graphene platelets as defined herein,
c) Applying the nanoscale graphene platelets from step b) to at least a part of the surface of the magnesium alloy from step a) to produce a composite material.

The process according to an aspect of the invention is suitable for producing the composite material as described in the preceding text and involves low production expenditure while improving the mechanical and chemical properties.

Thus, according to step a) an aspect of the process according to the invention is that a magnesium alloy be prepared.

Regarding the magnesium alloy, the further alloy components and the quantities thereof in the magnesium alloy, reference is made to the definitions given above in relation to the magnesium alloy and the embodiments thereof.

In order to reduce contact corrosion between the surface of the magnesium alloy and the layer consisting of nanoscale graphene platelets, and to improve adhesion of the layer consisting of nano scale graphene platelets to the surface of the magnesium alloy, it is advantageous if the surface of the magnesium alloy is pretreated.

In one embodiment, the magnesium alloy is pretreated by application of an organic or inorganic coating. If it is carried out, pretreatment of the magnesium alloy surface takes place before step c).

Pretreatment of the magnesium alloy surface is preferably carried out by applying an organic or inorganic coating to the magnesium alloy, which serves to lower the surface conductivity of the precoated alloy. For this, for example, an organic coating or an inorganic coating may be applied to the surface of the magnesium alloy. Such processes for pretreatment and corresponding coatings are known from the state of the art, for instance Ardrox 1769 or Oxsilan 9802 manufactured by Chemetall GmbH, Germany. In one embodiment, the surface of the magnesium alloy may be rinsed with water after the organic or inorganic coating has been applied.

In one embodiment, the surface of the magnesium alloy is cleaned before the coating is applied. Corresponding cleaning steps are known from the state of the art. For example, the surface of the magnesium alloy may be cleaned by treating with an alkaline cleaning agent, rinsing with water, treating with an acid cleaning agent and rinsing with water before the organic or inorganic coating is applied. Corresponding alkaline and acid cleaning agents are known from the state of the art.

According to step b) of the process according to an aspect of the invention, nanoscale graphene platelets are prepared.

With regard to the nanoscale graphene platelets, reference is made to the definitions in the preceding text relating to the nanoscale graphene platelets and embodiments thereof.

According to step c) a further aspect of the process according to the invention is that the nanoscale graphene platelets of step b) be applied to at least a part of the magnesium alloy surface of step a) in order to produce a composite material.

The application of the nanoscale graphene platelets to at least a part of the magnesium alloy surface in step c) may be carried out in a number of different processes. Typically, the application of the nanoscale graphene platelets to at least a part of the magnesium alloy surface in step c) can be performed by chemical vapour deposition (CVD), epitaxial growth or deposition from an organic matrix. Methods for chemical vapour deposition (CVD), epitaxial growth or deposition from an organic matrix are known from the state of the art.

If the application of the nanoscale graphene platelets to at least a part of the magnesium alloy surface in step c) is performed by deposition from an organic matrix, thermal post-treatment may be carried out after the nanoscale graphene platelets have been applied in step c) to restore the intrinsic properties of the graphene and cure the layer consisting of nanoscale graphene platelets on the surface of the magnesium alloy.

Thermal post-treatment preferably takes place in a temperature range from 100 to 500° C. depending on the organic matrix used. For example, thermal post-treatment may take place in a temperature range from 100 to 300° C.

In one embodiment of the present invention, thermal post-treatment takes place in a temperature range from 100 to 500° C., for example in a temperature range from 100 to 300° C. for a period of 10 min to 50 h. Thermal post-treatment may typically take place at temperatures between 100 and 500° C., for example in a temperature range from 100 to 300° C. for a period of 10 min to 10 h. For example, thermal post-treatment is carried out at temperatures between 100 and 500° C., for example for example in a temperature range from 100 to 300° C. for a period of 10 min to 5 h or for a period of 30 min to 3 h. For example, thermal post-treatment may be carried out for example in air, inert gas, or vacuum, for example in a vacuum.

Processes for thermal post-treatment of composite materials in a temperature range from 100 to 500° C. are known from the state of the art.

In view of the advantages offered by the composite material according to an embodiment of the invention, the present invention also relates to the use of the composite material in a passenger transport vehicle, helicopter or an unmanned aircraft, in a spacecraft, a transport vehicle, particularly in railways and ships, in automobile construction, plant construction, machine building or toolmaking. For example, the composite material according to the invention may be used in aircraft such as passenger airliners. In particular, the composite material according to the invention is used as a composite material in an airframe.

While at least one exemplary embodiment of the present invention(s) is disclosed herein, it should be understood that modifications, substitutions and alternatives may be apparent to one of ordinary skill in the art and can be made without departing from the scope of this disclosure. This disclosure is intended to cover any adaptations or variations of the exemplary embodiment(s). In addition, in this disclosure, the terms “comprise” or “comprising” do not exclude other elements or steps, the terms “a” or “one” do not exclude a plural number, and the term “or” means either or both. Furthermore, characteristics or steps which have been described may also be used in combination with other characteristics or steps and in any order unless the disclosure or context suggests otherwise. This disclosure hereby incorporates by reference the complete disclosure of any patent or application from which it claims benefit or priority.

1. A composite material comprising:
a) a magnesium alloy; and
b) a layer of nanoscale graphene platelets on at least a part of the magnesium alloy surface.

2. The composite material according to claim 1, wherein the magnesium alloy comprises at least one component selected from the group consisting of yttrium (Y), neodymium (Nd), terbium (Tb), dysprosium (Dy), holmium (Ho), erbium (Er), thulium (Tm), ytterbium (Yb), lutetium (Lu), zirconium (Zr), zinc (Zn), gadolinium (Gd), scandium (Sc), lanthanum (La), cerium (Ce), praseodymium (Pr), promethium (Pm), samarium (Sm), europium (Er) aluminium (Al), calcium (Ca), silicon (Si), manganese (Mn), lithium (Li), silver (Ag) and mixtures thereof as a further alloy component.

3. The composite material according to claim 1, wherein the magnesium alloy comprises magnesium in a quantity from 80 to 98% by weight relative to the total weight of the magnesium alloy.

4. The composite material according to claim 1, wherein the layer of nanoscale graphene platelets is substantially present over the entire surface of the magnesium alloy.

5. The composite material according to claim 1, wherein the layer of nanoscale graphene platelets has a layer thickness from 10 to 1,000 nm.

6. The composite material according to claim 1, wherein the layer of nanoscale graphene platelets includes multiple layers.

7. The composite material according to claim 1, wherein the nanoscale graphene platelets have a thickness from 1 to 100 nm and/or a length, width or diameter of ≦100 μm.

8. The composite material according to claim 1, wherein the nanoscale graphene platelets are obtained by mechanical or chemical processes.

9. The composite material according to claim 1, wherein the layer of nanoscale graphene platelets has:
a) a thermal conductivity from ≧1 Wm⁻¹K⁻¹, and/or
b) a melting temperature from ≧3725° C., and/or
c) a tensile strength from 1 to 10 GPa, and/or
d) an electrical conductivity of ≦10⁷ Ω⁻¹cm⁻¹.

10. A method for producing a composite material according to claim 1, wherein the process comprises:
a) providing a magnesium alloy, as defined in claim 1;
b) providing nanoscale graphene platelets having a thickness from 1 to 100 nm and/or a length, width or diameter of ≦100 μm or obtained by mechanical or chemical processes;
c) applying the nanoscales graphene platelets from step b) to at least a part of the surface of the magnesium alloy from step a) for producing a composite material.

11. The method according to claim 10, wherein the application of the nanoscale graphene platelets to a least a part of the surface of the magnesium alloy in step c) is effected by chemical vapour deposition (CVD), epitaxial growth or deposition from an organic matrix.

12. The method according to claim 10, wherein the magnesium alloy is pretreated before step c) by the application of an organic or inorganic coating.
